(19) United States
(12) Patent Application Publication
(10) Pub. No.: US 2026/0240000 A1
(43) Pub. Date: Aug. 13, 2026

(54) SEMICONDUCTOR DEVICE, AND PACKAGE OF SEMICONDUCTOR DEVICE

(71) Applicant: ROHM CO., LTD., Kyoto-shi (JP)

(72) Inventors: Koki NAKANO, Kyoto-shi (JP); Hideaki YAMAJI, Kyoto-shi (JP)

(21) Appl. No.: 19/638,191

(22) Filed: Apr. 3, 2026

Related U.S. Application Data
(63) Continuation of application No. PCT/JP2024/033493, filed on Sep. 19, 2024.

(30) Foreign Application Priority Data
Oct. 11, 2023 (JP) 2023-176013

(51) Int. Cl. H10W 70/40; H10W 74/10; H10W 90/00

(52) U.S. Cl. CPC H10W 70/429; H10W 70/457; H10W 74/111; H10W 90/701

(57) ABSTRACT

The semiconductor device is configured to improve the bonding strength to a wiring board. The semiconductor device includes a first lead, a semiconductor element, and a sealing resin. The semiconductor element is electrically connected to the first lead. The sealing resin covers a part of the first lead, and the semiconductor element. The first lead has a first outer portion protruding from the sealing resin. The first outer portion has a first mounting surface facing one side in a first direction. The first outer portion has a first opening penetrating the first outer portion from the first mounting surface.

### FIELD

The present disclosure relates to a semiconductor device and a mounted assembly in which the semiconductor device is mounted on a wiring board.

### BACKGROUND

JP-A-2017-168553 discloses an example of a semiconductor device that includes a first lead, a second lead, a semiconductor element conductively bonded to each of the first lead and the second lead, and a sealing resin covering the semiconductor element. The second lead carries the semiconductor element. A part of each of the first lead and the second lead is exposed from the sealing resin. The parts of the first lead and the second lead that are exposed from the sealing resin are covered with an external plating layer. The external plating layer contains tin. Thus, when the semiconductor device is mounted on a wiring board, solder readily wets the parts of the first lead and the second lead that are exposed from the sealing resin. As a result, the contact areas of the first and second leads with the solder can be increased.

When attempting to reduce the size of the semiconductor device disclosed in JP-A-2017-168553, the surface areas of the parts of the first lead and the second lead that are exposed from the sealing resin become smaller. This raises concerns that the bonding strength (mounting strength) of the semiconductor device to the wiring board may be reduced.

### DRAWINGS

FIG. 1 is a plan view of a semiconductor device according to a first embodiment of the present disclosure.

FIG. 2 is a plan view corresponding to FIG. 1, as seen through a sealing resin.

FIG. 3 is a bottom view of the semiconductor device shown in FIG. 1.

FIG. 4 is a front view of the semiconductor device shown in FIG. 1.

FIG. 5 is a left side view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a bottom view of a semiconductor device according to a variation of the first embodiment of the present disclosure.

FIG. 10 is a sectional view of the semiconductor device shown in FIG. 9 and corresponds to FIG. 8.

FIG. 11 is a sectional view of a mounted assembly according to a first embodiment of the present disclosure.

FIG. 12 is a partial enlarged sectional view of the mounted assembly shown in FIG. 11.

FIG. 13 is a bottom view of a semiconductor device according to a second embodiment of the present disclosure.

FIG. 14 is a left side view of the semiconductor device shown in FIG. 13.

FIG. 15 is a sectional view of the semiconductor device shown in FIG. 13 and corresponds to FIG. 6.

FIG. 16 is a sectional view of the semiconductor device shown in FIG. 13 and corresponds to FIG. 7.

FIG. 17 is a partial enlarged sectional view of a mounted assembly according to a second embodiment of the present disclosure.

FIG. 18 is a bottom view of a semiconductor device according to a third embodiment of the present disclosure.

FIG. 19 is a left side view of the semiconductor device shown in FIG. 18.

FIG. 20 is a sectional view of the semiconductor device shown in FIG. 18 and corresponds to FIG. 8.

FIG. 21 is a partial enlarged sectional view of a mounted assembly according to a third embodiment of the present disclosure.

FIG. 22 is a bottom view of a semiconductor device according to a fourth embodiment of the present disclosure.

FIG. 23 is a sectional view of the semiconductor device shown in FIG. 22 and corresponds to FIG. 6.

FIG. 24 is a partial enlarged sectional view of a mounted assembly according to a fourth embodiment of the present disclosure.

FIG. 25 is a bottom view of a semiconductor device according to a fifth embodiment of the present disclosure.

FIG. 26 is a sectional view of the semiconductor device shown in FIG. 25 and corresponds to FIG. 6.

FIG. 27 is a sectional view of the semiconductor device shown in FIG. 25 and corresponds to FIG. 8.

FIG. 28 is a bottom view of a semiconductor device according to a first variation of the fifth embodiment of the present disclosure.

FIG. 29 is a sectional view of the semiconductor device shown in FIG. 28 and corresponds to FIG. 26.

FIG. 30 is a bottom view of a semiconductor device according to a second variation of the fifth embodiment of the present disclosure.

FIG. 31 is a sectional view of the semiconductor device shown in FIG. 30 and corresponds to FIG. 27.

FIG. 32 is a partial enlarged sectional view of a mounted assembly according to a fifth embodiment of the present disclosure.

FIG. 33 is a bottom view of a semiconductor device according to a sixth embodiment of the present disclosure.

FIG. 34 is a sectional view of the semiconductor device shown in FIG. 33 and corresponds to FIG. 6.

FIG. 35 is a partial enlarged sectional view of a mounted assembly according to a sixth embodiment of the present disclosure.

FIG. 36 is a plan view of a semiconductor device according to a seventh embodiment of the present disclosure.

FIG. 37 is a bottom view of the semiconductor device shown in FIG. 36.

FIG. 38 is a sectional view of the semiconductor device shown in FIG. 36 and corresponds to FIG. 8.

### DETAILED DESCRIPTION

The present disclosure will be described in detail based on the accompanying drawings.

First embodiment:

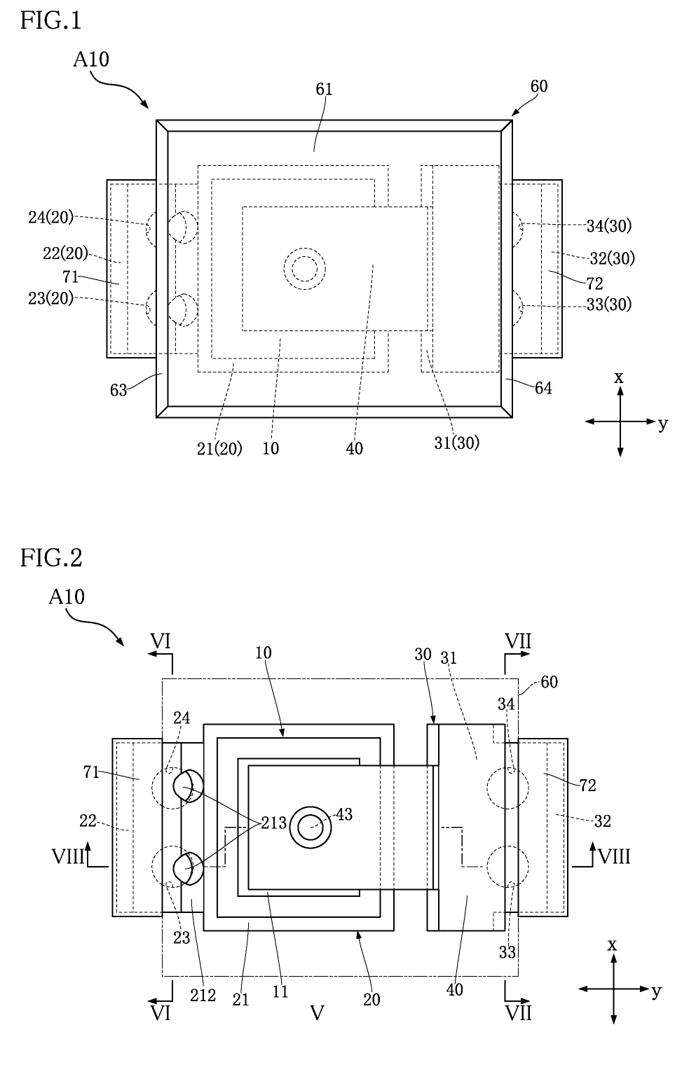

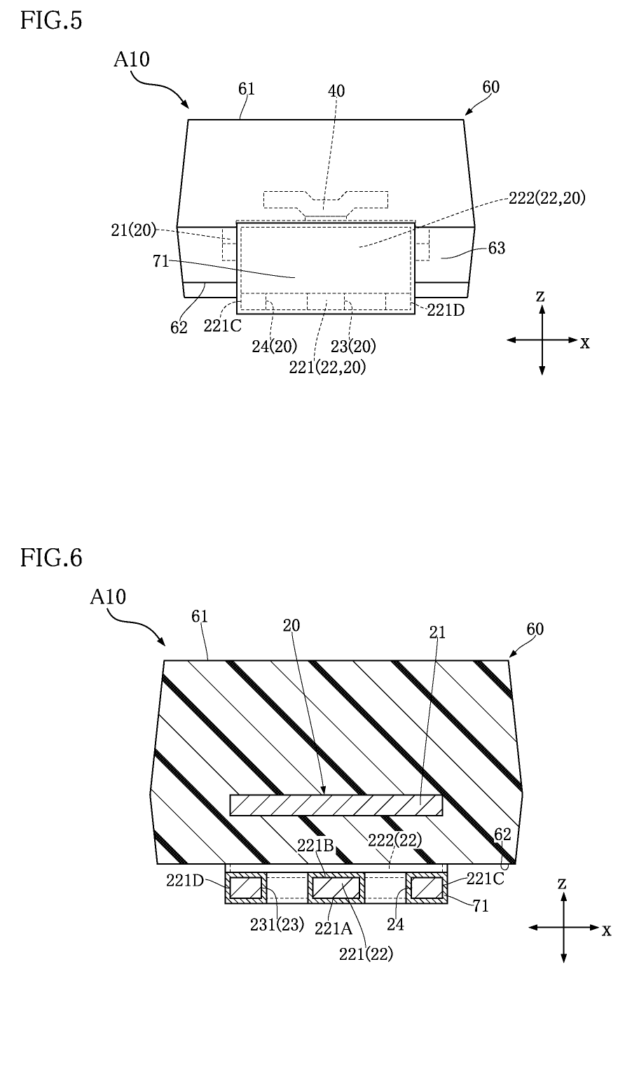

A semiconductor device A10 according to a first embodiment of the present disclosure will be described based on FIGS. 1 to 8. The semiconductor device A10 includes a semiconductor element 10, a first lead 20, a second lead 30, a conductive member 40, a first bonding layer 51, a second bonding layer 52, a third bonding layer 53, a sealing resin 60, a first protective layer 71, and a second protective layer 72. The semiconductor device A10 is of a resin-package type that is surface-mounted on a wiring board 80 described later. FIG. 2 is illustrated as seen through the sealing resin 60 for ease of understanding. In FIG. 2, the sealing resin 60 is indicated by imaginary lines (two-dot chain lines).

For convenience, in the following description, the direction normal to the top surface 61 of the sealing resin 60, described later, is referred to as the "first direction z". A direction orthogonal to the first direction z is referred to as the "second direction x". The direction orthogonal to the first direction z and the second direction x is referred to as the "third direction y".

As shown in FIG. 8, the sealing resin 60 covers the semiconductor element 10 and the conductive member 40. The sealing resin 60 also covers a part of each of the first lead 20 and the second lead 30. The sealing resin 60 has electrical insulating properties. The sealing resin 60 is made of a material containing, for example, a black epoxy resin. As shown in FIG. 4, the sealing resin 60 has a top surface 61, a bottom surface 62, a first side surface 63, and a second side surface 64.

As shown in FIGS. 6 and 8, the top surface 61 faces the same side as the mounting surface 211 of the first inner portion 21 of the first lead 20, described later, in the first direction z. The bottom surface 62 faces away from the top surface 61 in the first direction z.

As shown in FIGS. 1 and 4, the second side surface 64 and the first side surface 63 face away from each other in the third direction y. Each of the first side surface 63 and the second side surface 64 is connected to the top surface 61 and the bottom surface 62.

As shown in FIGS. 2 and 8, the semiconductor element 10 is mounted on the first lead 20. The semiconductor element 10 is electrically connected to the first lead 20 and the second lead 30. In the semiconductor device A10, the semiconductor element 10 is a Schottky barrier diode. Alternatively, the semiconductor element 10 may be various types of elements, such as diodes other than Schottky barrier diodes, or transistors.

As shown in FIG. 8, the semiconductor element 10 has a first electrode 11 and a second electrode 12. The first electrode 11 and the second electrode 12 are located on opposite sides of each other in the first direction z. The first electrode 11 is electrically connected to the second lead 30. The first electrode 11 is an anode. The first electrode 11 is, for example, composed of an aluminum (Al) layer, a nickel (Ni) layer, and a palladium (Pd) layer laminated in this order. In the semiconductor device A10, a Schottky barrier is formed by the presence of a thin metal film interposed between the semiconductor layer constituting the semiconductor element 10 and the first electrode 11. This thin metal film is, for example, made of molybdenum (Mo) or titanium (Ti). The second electrode 12 is electrically connected to the first lead 20. The second electrode 12 is a cathode.

The first lead 20, the second lead 30, and the conductive member 40 form an electrical conduction path between the semiconductor element 10 and the wiring board on which the semiconductor device A10 is mounted. Among these, the first lead 20 and the second lead 30 are obtained from the same lead frame and correspond to terminals mounted on the wiring board. The first lead 20, the second lead 30, and the conductive member 40 each contain copper (Cu).

As shown in FIGS. 1 and 2, the first lead 20 is located on one side in the third direction y. The first lead 20 includes a first inner portion 21 and a first outer portion 22. The first inner portion 21 is covered with the sealing resin 60. In the semiconductor device A10, the entire first inner portion 21 is covered with the sealing resin 60. Alternatively, a part of the first inner portion 21 may be exposed from the bottom surface 62 of the sealing resin 60. The first outer portion 22 is connected to the first inner portion 21. The first outer portion 22 protrudes from the first side surface 63 of the sealing resin 60. As shown in FIG. 4, the first outer portion 22 is bent around the second direction x so as to extend along the first side surface 63 and the bottom surface 62 of the sealing resin 60.

As shown in FIG. 8, the first inner portion 21 has a mounting surface 211 and an inclined surface 212. The mounting surface 211 faces the same side as the top surface 61 of the sealing resin 60 in the first direction z. The mounting surface 211 faces the second electrode 12 of the semiconductor element 10. In the first direction z, the mounting surface 211 is located between the bottom surface 62 of the sealing resin 60 and the third bonding surface 311 of the second lead 30 described later. The inclined surface 212 is located opposite the second lead 30 with respect to the mounting surface 211 in the third direction y and connected to the mounting surface 211. The inclined surface 212 is inclined relative to the mounting surface 211. As viewed in the third direction y, the inclined surface 212 overlaps with the semiconductor element 10. As shown in FIG. 2, the first inner portion 21 has two through-holes 213. The two through-holes 213 are spaced apart from each other in the second direction x. Each of the two through-holes 213 penetrates the first inner portion 21 from the inclined surface 212. The penetration direction of each of the two through-holes 213 corresponds to the direction normal to the inclined surface 212.

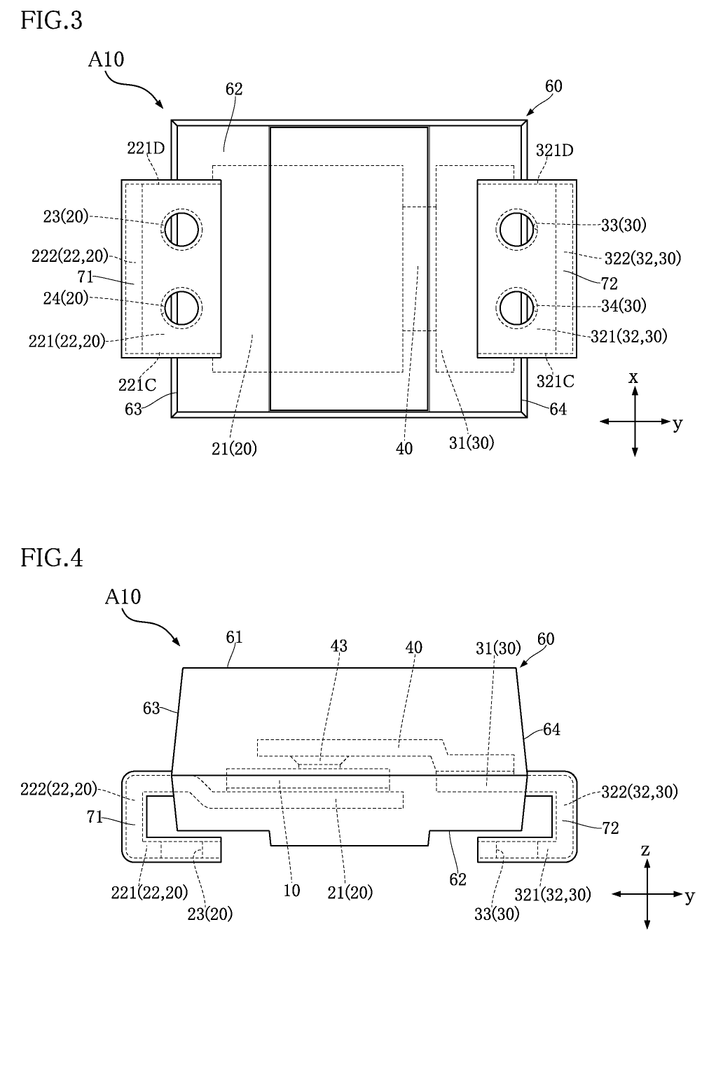

As shown in FIGS. 3 to 6 and 8, the first outer portion 22 has a first mounting portion 221 and a first intermediate portion 222. The first mounting portion 221 is located opposite the first inner portion 21 with respect to the first intermediate portion 222. The first mounting portion 221 faces the sealing resin 60. The first intermediate portion 222 rises from the first mounting portion 221 in the first direction z. The first intermediate portion 222 is connected to the first inner portion 21.

As shown in FIGS. 6 and 8, the first mounting portion 221 has a first mounting surface 221A, a first reverse surface 221B, a first end surface 221C, a second end surface 221D, and a third end surface 221E. The first mounting surface 221A faces one side in the first direction z. The first reverse surface 221B faces away from the first mounting surface 221A in the first direction z. The first reverse surface 221B faces the bottom surface 62 of the sealing resin 60. In the first direction z, a gap is provided between the first reverse surface 221B and the bottom surface 62. The first end surface 221C and the second end surface 221D face away from each other in the second direction x. The third end surface 221E faces the side opposite to the side on which the first intermediate portion 222 is located with respect to the first mounting portion 221 in the third direction y.

As shown in FIGS. 1 to 3, 5, and 6, the first mounting portion 221 has a first opening 23 and a second opening 24. Each of the first opening 23 and the second opening 24 penetrates the first outer portion 22 from the first mounting surface 221A of the first mounting portion 221. The second opening 24 is spaced apart from the first opening 23 in the second direction x. The first opening 23 is spaced apart from the first end surface 221C of the first mounting portion 221. The second opening 24 is spaced apart from the second end surface 221D of the first mounting portion 221. The second opening 24 is located between the first end surface 221C and the first opening 23 in the second direction x. In the semiconductor device A10, as viewed in the first direction z, the first opening 23 and the second opening 24 are located inward of the peripheral edge of the first mounting portion 221. As viewed in the first direction z, the first opening 23 and the second opening 24 overlap with the sealing resin 60.

As shown in FIGS. 6 and 8, the first mounting portion 221 has an inner peripheral surface 231 that defines the first opening 23. The inner peripheral surface 231 is connected to the first mounting surface 221A and the first reverse surface 221B of the first mounting portion 221. In the semiconductor device A10, the size of the cross section of the first opening 23 taken orthogonal to the first direction z is uniform from the first mounting surface 221A to the first reverse surface 221B.

The first protective layer 71 covers at least a part of the first outer portion 22 of the first lead 20 as shown in FIGS. 6 and 8. In the semiconductor device A10, the first protective layer 71 covers the parts of the first mounting portion 221 excluding the third end surface 221E and the entire first intermediate portion 222. Thus, the first protective layer 71 covers the first mounting surface 221A, the first reverse surface 221B, the first end surface 221C, the second end surface 221D, and the inner peripheral surface 231 of the first mounting portion 221. The first protective layer 71 is conductive. The first protective layer 71 is, for example, a metal containing tin (Sn). Alternatively, the first protective layer 71 may be composed of a plurality of metal layers laminated in the order of a nickel layer, a palladium layer, and a gold (Au) layer from the side closer to the first outer portion 22.

The second lead 30 is spaced apart from the first lead 20 in the third direction y as shown in FIGS. 1 and 2. The second lead 30 includes a second inner portion 31 and a second outer portion 32. The second inner portion 31 is covered with the sealing resin 60. The second inner portion 31 has a third bonding surface 311 that faces the same side as the top surface 61 of the sealing resin 60 in the first direction z. The second outer portion 32 is connected to the second inner portion 31. The second outer portion 32 protrudes from the second side surface 64 of the sealing resin 60. As shown in FIG. 4, the second outer portion 32 is bent around the second direction x so as to extend along the second side surface 64 and the bottom surface 62 of the sealing resin 60.

As shown in FIGS. 3 to 5, 7, and 8, the second outer portion 32 has a second mounting portion 321 and a second intermediate portion 322. The second mounting portion 321 is located opposite the second inner portion 31 with respect to the second intermediate portion 322. The second mounting portion 321 faces the sealing resin 60. The second intermediate portion 322 rises from the second mounting portion 321 in the first direction z. The second intermediate portion 322 is connected to the second inner portion 31.

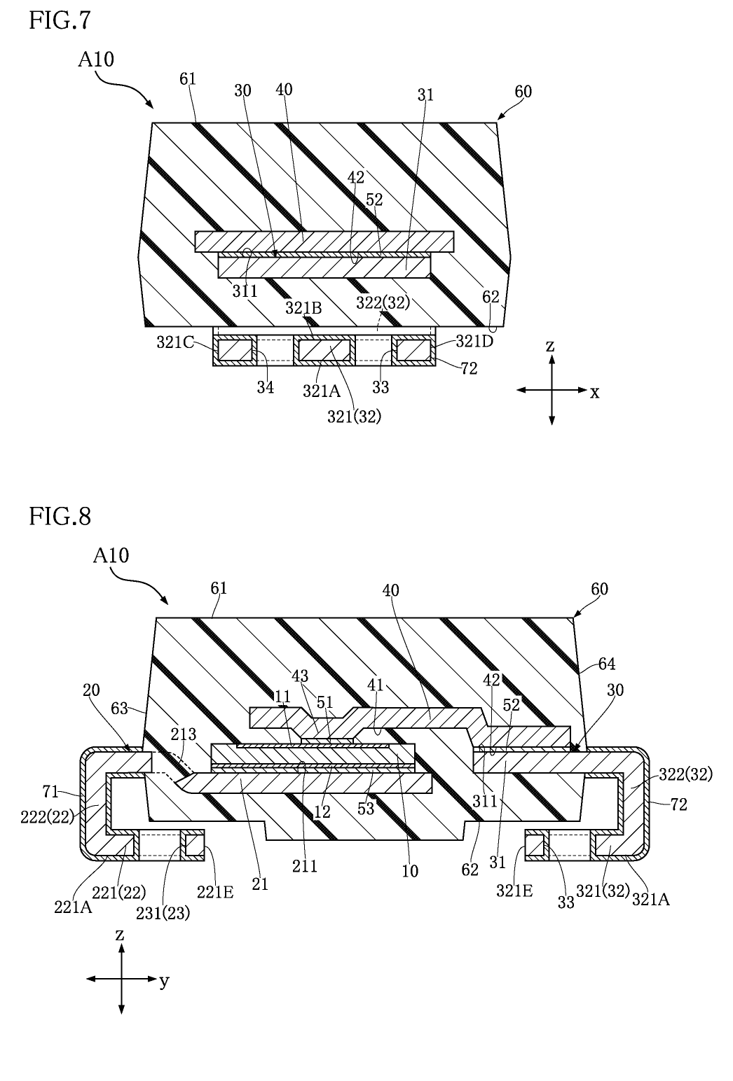

As shown in FIGS. 7 and 8, the second mounting portion 321 has a second mounting surface 321A, a second reverse surface 321B, a fourth end surface 321C, a fifth end surface 321D, and a sixth end surface 321E. The second mounting surface 321A faces the same side as the first mounting surface 221A of the first outer portion 22 of the first lead 20 in the first direction z. The second reverse surface 321B faces away from the second mounting surface 321A in the first direction z. The second reverse surface 321B faces the bottom surface 62 of the sealing resin 60. In the first direction z, a gap is provided between the second reverse surface 321B and the bottom surface 62. The fourth end surface 321C and the fifth end surface 321D face away from each other in the second direction x. The sixth end surface 321E faces the side opposite to the side on which the second intermediate portion 322 is located with respect to the second mounting portion 321 in the third direction y.

As shown in FIGS. 1 to 3 and 7, the second mounting portion 321 has a third opening 33 and a fourth opening 34. Each of the third opening 33 and the fourth opening 34 penetrates the second outer portion 32 from the second mounting surface 321A of the second mounting portion 321. The fourth opening 34 is spaced apart from the third opening 33 in the second direction x. The third opening 33 is spaced apart from fourth end surface 321C of the second mounting portion 321. The fourth opening 34 is spaced apart from the fifth end surface 321D of the second mounting portion 321. The fourth opening 34 is located between the fourth end surface 321C and the third opening 33 in the second direction x. In the semiconductor device A10, as viewed in the first direction z, the third opening 33 and the fourth opening 34 are located inward of the peripheral edge of the second mounting portion 321. As viewed in the first direction z, the third opening 33 and the fourth opening 34 overlap with the sealing resin 60.

The second protective layer 72 covers at least a part of the second outer portion 32 of the second lead 30 as shown in FIGS. 7 and 8. In the semiconductor device A10, the second protective layer 72 covers the parts of the second mounting portion 321 excluding the sixth end surface 321E and the entire second intermediate portion 322. Thus, the second protective layer 72 covers the second mounting surface 321A, the second reverse surface 321B, the fourth end surface 321C, and the fifth end surface 321D of the second mounting portion 321. The second protective layer 72 is conductive. The composition of the second protective layer 72 is the same as that of the first protective layer 71.

As shown in FIG. 8, the conductive member 40 is conductively bonded to the second inner portion 31 of the second lead 30 and the first electrode 11 of the semiconductor element 10. The conductive member 40 is a metal clip. The conductive member 40 has a first bonding surface 41 and a second bonding surface 42. The first bonding surface 41 faces the first electrode 11. The second bonding surface 42 faces the third bonding surface 311 of the second inner portion 31.

As shown in FIG. 8, the conductive member 40 has a protrusion 43 protruding from the first bonding surface 41. As shown in FIG. 2, as viewed in the first direction z, the protrusion 43 overlaps with the first electrode 11 of the semiconductor element 10.

As shown in FIG. 8, the first bonding layer 51 conductively bonds the first electrode 11 of the semiconductor element 10 and the conductive member 40. The first bonding layer 51 is solder. The first bonding layer 51 is located between the first electrode 11 and the protrusion 43 of the conductive member 40.

As shown in FIGS. 7 and 8, the second bonding layer 52 conductively bonds the second inner portion 31 of the second lead 30 and the conductive member 40. The second bonding layer 52 is solder. The second bonding layer 52 is located between the third bonding surface 311 of the second inner portion 31 and the second bonding surface 42 of the conductive member 40.

As shown in FIG. 8, the third bonding layer 53 conductively bonds the first inner portion 21 of the first lead 20 and the second electrode 12 of the semiconductor element 10. The third bonding layer 53 is solder. The third bonding layer 53 is located between the mounting surface 211 of the first inner portion 21 and the second electrode 12.

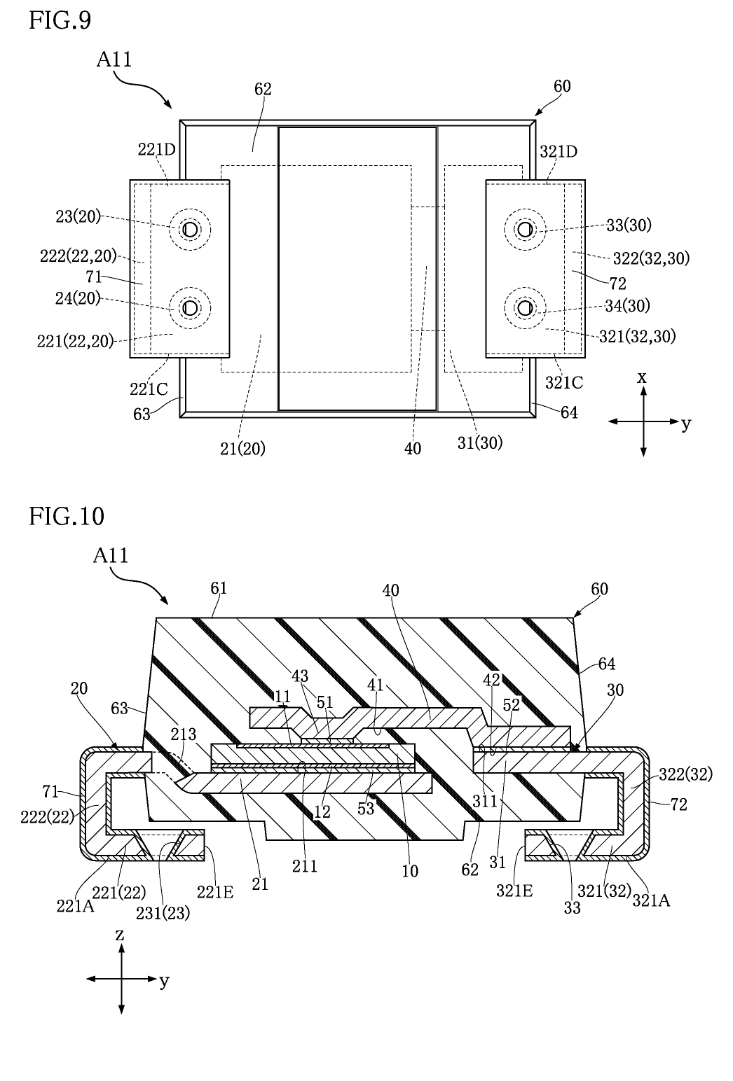

Next, a semiconductor device A11, which is a variation of the semiconductor device A10, will be described based on FIGS. 9 and 10. The cross-sectional position in FIG. 10 corresponds to the cross-sectional position in FIG. 8.

As shown in FIGS. 9 and 10, the size of the cross section of the first opening 23 in the direction orthogonal to the first direction z increases from the first mounting surface 221A to the first reverse surface 221B of the first mounting portion 221. The inner peripheral surface 231 of the first mounting portion 221, which defines the first opening 23, is inclined relative to the first mounting surface 221A.

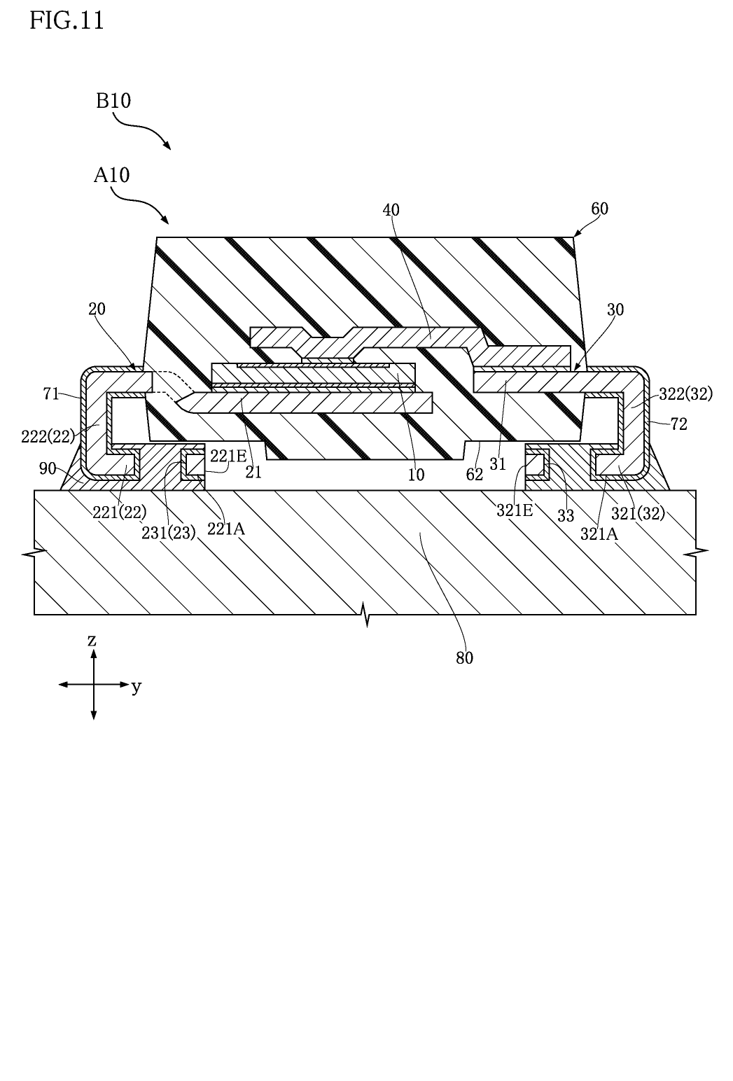

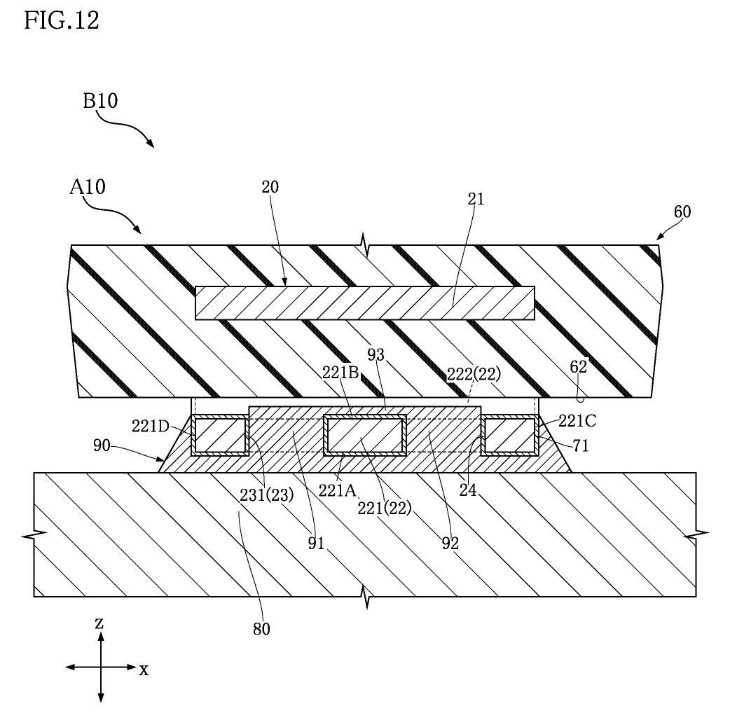

Next, a mounted assembly according to a first embodiment of the present disclosure (hereinafter referred to as "mounted assembly B10") will be described based on FIGS. 11 and 12. The mounted assembly B10 includes the semiconductor device A10, a wiring board 80, and a bonding layer 90.

The wiring board 80 is an object on which the semiconductor device A10 is mounted. As shown in FIG. 11, the wiring board 80 faces the first mounting surface 221A of the first outer portion 22 of the first lead 20 and the second mounting surface 321A of the second outer portion 32 of the second lead 30. The bonding layer 90 conductively bonds the wiring board 80 and the first outer portion 22. Also, the bonding layer 90 conductively bonds the wiring board 80 and the second outer portion 32. The bonding layer 90 is solder.

As shown in FIG. 12, the bonding layer 90 includes a first bonding portion 91, a second bonding portion 92, and a third bonding portion 93. The first bonding portion 91 is received in the first opening 23. The second bonding portion 92 is received in the second opening 24. The third bonding portion 93 is located opposite the first mounting surface 221A of the first mounting portion 221 with respect to the first reverse surface 221B of the first mounting portion 221 of the first outer portion 22 in the first direction z. The third bonding portion 93 is connected to the first bonding portion 91 and the second bonding portion 92. Thus, in the mounted assembly B10, the bonding layer 90 surrounds the part of the first mounting portion 221 located between the first opening 23 and the second opening 24, as viewed in the third direction y.

Next, the effects of the semiconductor device A10 will be described.

The semiconductor device A10 includes the first lead 20, the semiconductor element 10, and the sealing resin 60. The first lead 20 has the first outer portion 22 protruding from the sealing resin 60. The first outer portion 22 has the first mounting surface 221A facing one side in the first direction z. The first outer portion 22 has the first opening 23 penetrating the first outer portion 22 from the first mounting surface 221A. With this configuration, in the mounted assembly B10 shown in FIG. 12, the first bonding portion 91, which is a part of the bonding layer 90, is received in the first opening 23. As a result, the bonding layer 90 exerts an anchoring effect on the first outer portion 22. Furthermore, in the mounted assembly B10, the bonding layer 90 surrounds a part of the first outer portion 22 as viewed in the first direction z. As a result, the first outer portion 22 is constrained in the first direction z with respect to the wiring board 80. Therefore, the present configuration can improve the bonding strength between the semiconductor device A10 and the wiring board 80.

The semiconductor device A10 further includes the first protective layer 71 that covers at least a part of the first outer portion 22 and that is conductive. The first protective layer 71 covers the first end surface 221C of the first outer portion 22. With this configuration, the wettability of the bonding layer 90 to the first outer portion 22 can be improved in the mounted assembly B10 shown in FIG. 11. Furthermore, a part of the bonding layer 90 can more readily climb up the first end surface 221C. This effectively improves the bonding strength of the semiconductor device A10 to the wiring board 80.

The first protective layer 71 covers the first reverse surface 221B of the first outer portion 22. With this configuration, the first protective layer 71 promotes the formation of the third bonding portion 93, which is a part of the bonding layer 90, in the mounted assembly B10. As a result, the first outer portion 22 can be firmly constrained with respect to the wiring board 80.

The first outer portion 22 has the inner peripheral surface 231 that defines the first opening 23. The first protective layer 71 covers the inner peripheral surface 231. This configuration allows the volume of the first bonding portion 91 in the mounted assembly B10 to be increased. As a result, the first outer portion 22 can be firmly constrained with respect to the wiring board 80.

The first reverse surface 221B of the first outer portion 22 faces the sealing resin 60. As viewed in the first direction z, the first opening 23 overlaps with the sealing resin 60. In the first direction z, a gap is provided between the first reverse surface 221B and the sealing resin 60. With this configuration, in the mounted assembly B10, the sealing resin 60 does not hinder the formation of the third bonding portion 93.

In the semiconductor device A11, the size of the cross section of the first opening 23 in the direction orthogonal to the first direction z increases from the first mounting surface 221A to the first reverse surface 221B of the first outer portion 22. With this configuration, in the mounted assembly B10, the bonding layer 90 flowing into the first opening 23 can readily reach the first reverse surface 221B. This further promotes the formation of the third bonding portion 93.

Second embodiment:

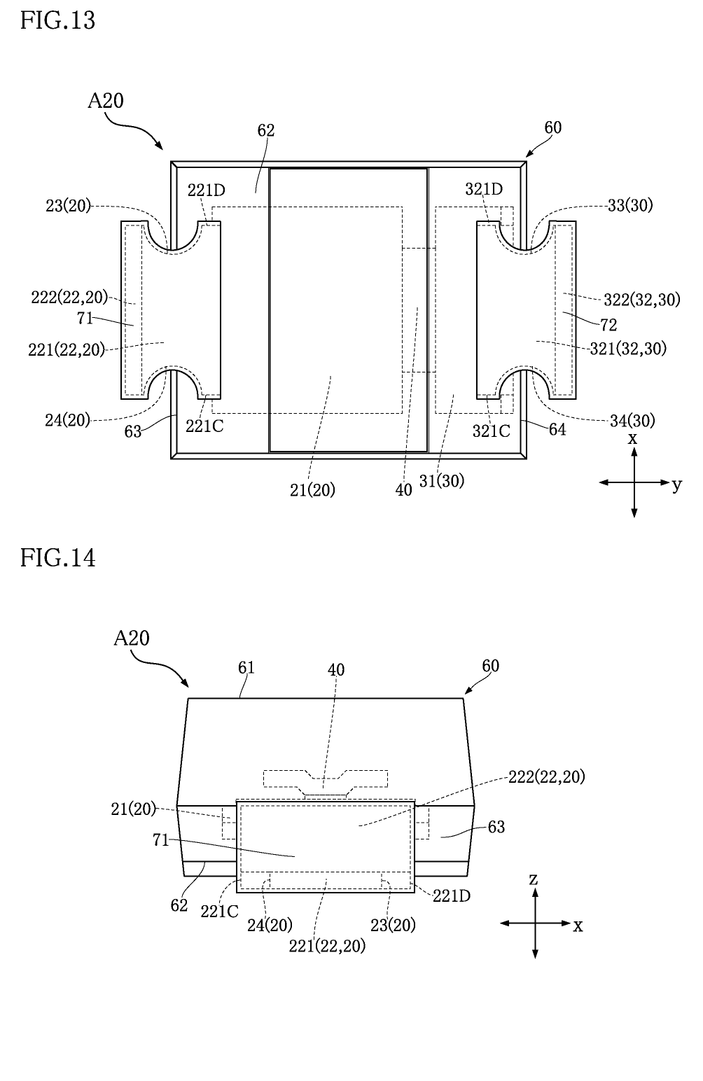

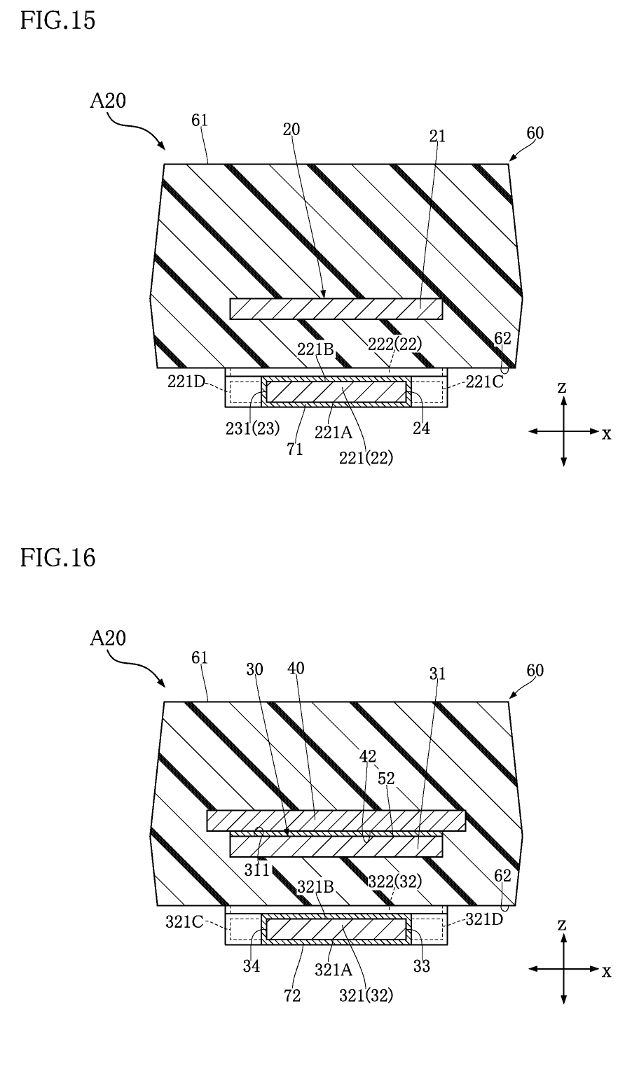

A semiconductor device A20 according to a second embodiment of the present disclosure will be described based on FIGS. 13 to 16. In these figures, the elements that are identical or similar to those of the semiconductor device A10 described above are denoted by the same reference signs, and the descriptions thereof are omitted. The cross-sectional position in FIG. 15 corresponds to the cross-sectional position in FIG. 6, which shows the semiconductor device A10. The cross-sectional position in FIG. 16 corresponds to the cross-sectional position in FIG. 7, which shows the semiconductor device A10.

The semiconductor device A20 differs from the semiconductor device A10 in the configurations of the first outer portion 22 of the first lead 20 and the second outer portion 32 of the second lead 30.

As shown in FIGS. 13 to 15, the first opening 23 provided in the first outer portion 22 is connected to the second end surface 221D of the first mounting portion 221. Thus, the first opening 23 opens from the second end surface 221D. The second opening 24 provided in the first outer portion 22 is connected to the first end surface 221C of the first mounting portion 221. Thus, the second opening 24 opens from the first end surface 221C.

As shown in FIGS. 13 and 16, the third opening 33 provided in the second outer portion 32 is connected to the fifth end surface 321D of the second mounting portion 321. Thus, the third opening 33 opens from the fifth end surface 321D. The fourth opening 34 provided in the second outer portion 32 is connected to the fourth end surface 321C of the second mounting portion 321. Thus, the fourth opening 34 opens from the fourth end surface 321C.

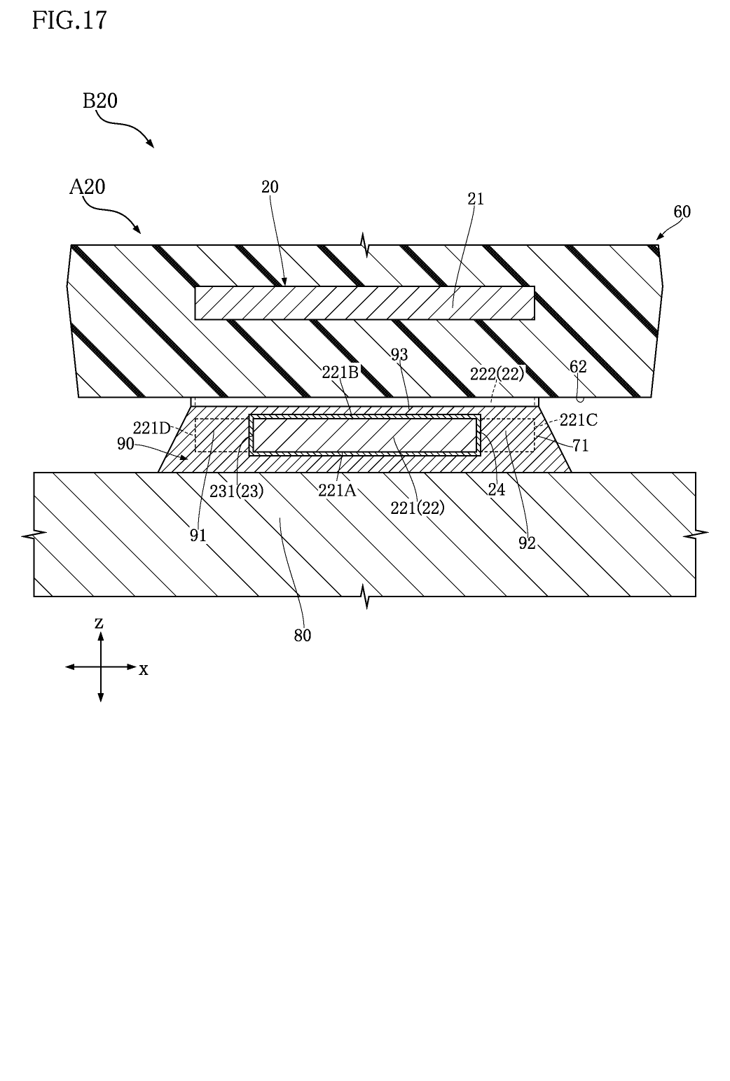

Next, a mounted assembly according to a second embodiment of the present disclosure (hereinafter referred to as "mounted assembly B20") will be described based on FIG. 17. The mounted assembly B20 includes the semiconductor device A20, a wiring board 80, and a bonding layer 90.

As shown in FIG. 17, the bonding layer 90 includes a first bonding portion 91, a second bonding portion 92, and a third bonding portion 93. As with the mounted assembly B10, the third bonding portion 93 is connected to the first bonding portion 91 and the second bonding portion 92. Thus, in the mounted assembly B20, the bonding layer 90 surrounds the part of the first mounting portion 221 located between the first opening 23 and the second opening 24, as viewed in the third direction y.

Next, the effects of the semiconductor device A20 will be described.

The semiconductor device A20 includes the first lead 20, the semiconductor element 10, and the sealing resin 60. The first lead 20 has the first outer portion 22 protruding from the sealing resin 60. The first outer portion 22 has the first mounting surface 221A facing one side in the first direction z. The first outer portion 22 has the first opening 23 penetrating the first outer portion 22 from the first mounting surface 221A. With such a configuration, the bonding strength to the wiring board 80 can be improved also in the semiconductor device A20. Furthermore, the semiconductor device A20 has a configuration in common with the semiconductor device A10, thereby achieving the same effect as the semiconductor device A10.

Third embodiment:

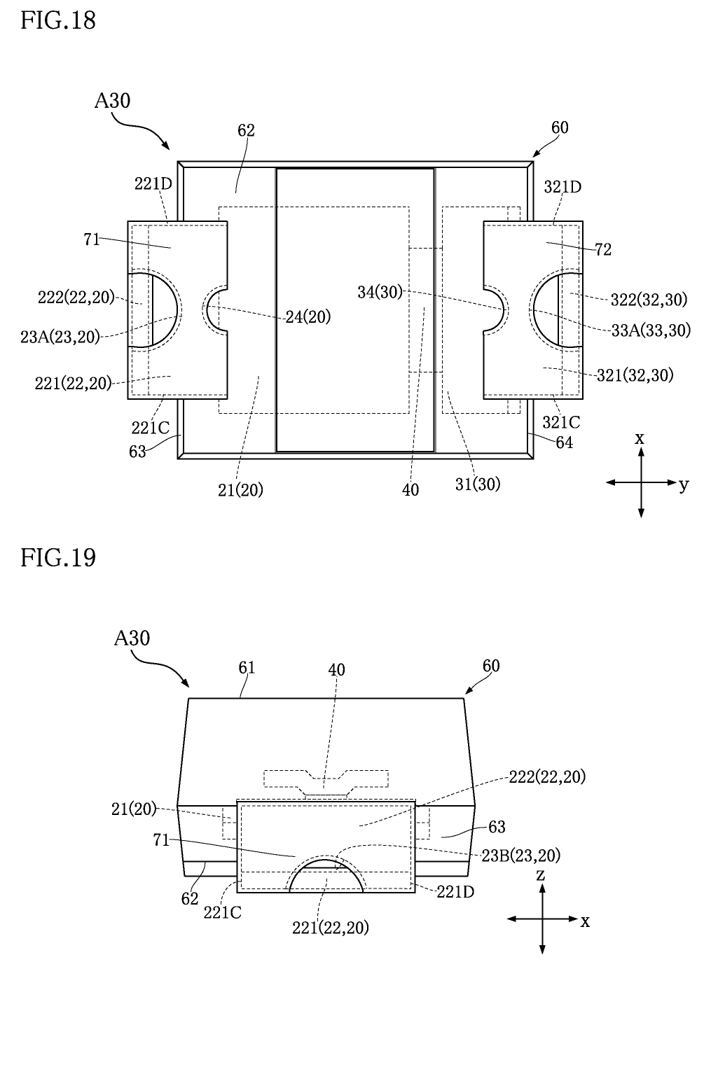

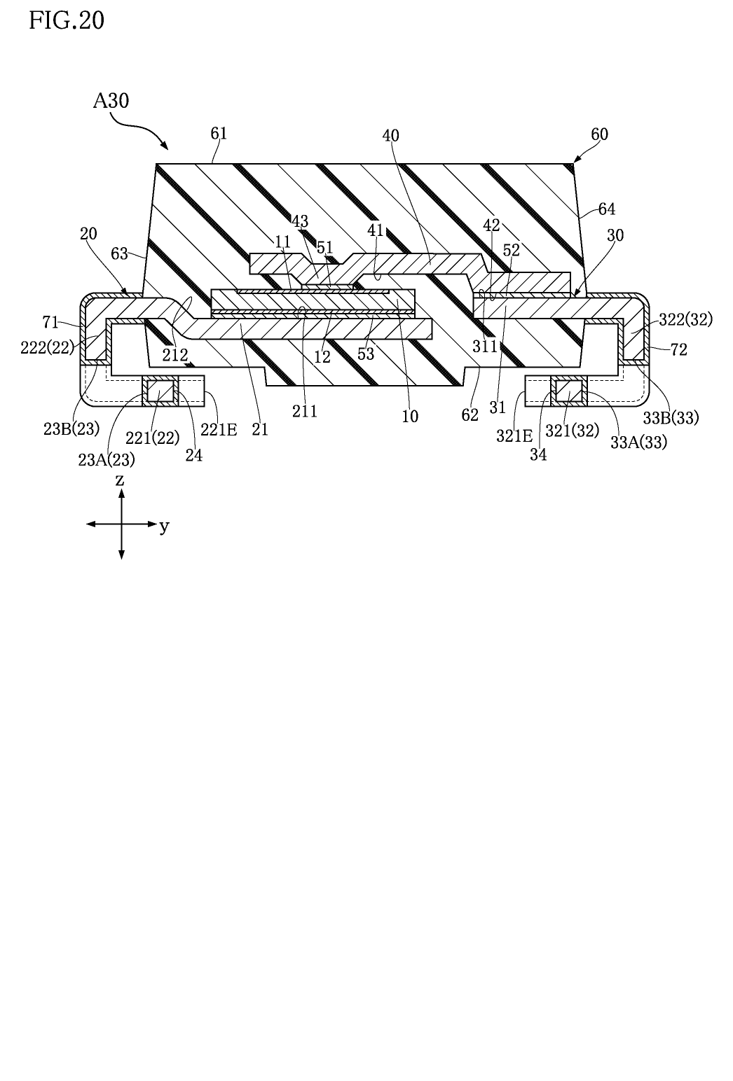

A semiconductor device A30 according to a third embodiment of the present disclosure will be described based on FIGS. 18 to 20. In these figures, the elements that are identical or similar to those of the semiconductor device A10 described above are denoted by the same reference signs, and the descriptions thereof are omitted. The cross-sectional position in FIG. 20 corresponds to the cross-sectional position in FIG. 8, which shows the semiconductor device A10.

The semiconductor device A30 differs from the semiconductor device A10 in the configurations of the first outer portion 22 of the first lead 20 and the second outer portion 32 of the second lead 30.

As shown in FIGS. 18 to 20, the first opening 23 provided in the first outer portion 22 includes a first portion 23A and a second portion 23B. The first portion 23A penetrates the first mounting portion 221 of the first outer portion 22 in the first direction z. The second portion 23B is connected to the first portion 23A and penetrates the first intermediate portion 222 of the first outer portion 22 in the third direction y. The second opening 24 provided in the first outer portion 22 is spaced apart from the first opening 23 in the third direction y. The second opening 24 is connected to the third end surface 221E of the first mounting portion 221. Thus, the second opening 24 opens from the third end surface 221E.

As shown in FIGS. 18 and 20, the third opening 33 provided in the second outer portion 32 includes a third portion 33A and a fourth portion 33B. The third portion 33A penetrates the second mounting portion 321 of the second outer portion 32 in the first direction z. The fourth portion 33B is connected to the third portion 33A and penetrates the second intermediate portion 322 of the second outer portion 32 in the third direction y. The fourth opening 34 provided in the second outer portion 32 is spaced apart from the third opening 33 in the third direction y. The fourth opening 34 is connected to the sixth end surface 321E of the second mounting portion 321. Thus, the fourth opening 34 opens from the sixth end surface 321E.

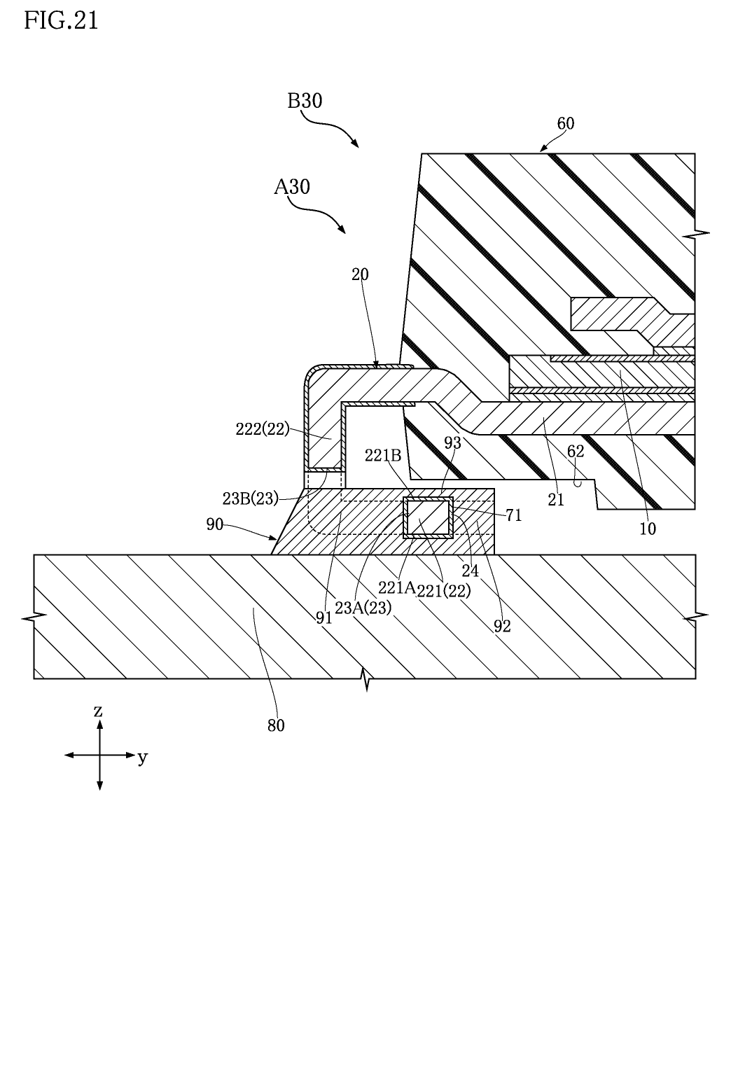

Next, a mounted assembly according to a third embodiment of the present disclosure (hereinafter referred to as "mounted assembly B30") will be described based on FIG. 21. The mounted assembly B30 includes the semiconductor device A30, a wiring board 80, and a bonding layer 90.

As shown in FIG. 21, the bonding layer 90 includes a first bonding portion 91, a second bonding portion 92, and a third bonding portion 93. As with the mounted assembly B10, the third bonding portion 93 is connected to the first bonding portion 91 and the second bonding portion 92. Thus, in the mounted assembly B30, the bonding layer 90 surrounds the part of the first mounting portion 221 located between the first opening 23 and the second opening 24, as viewed in the second direction x.

Next, the effects of the semiconductor device A30 will be described.

The semiconductor device A30 includes the first lead 20, the semiconductor element 10, and the sealing resin 60. The first lead 20 has the first outer portion 22 protruding from the sealing resin 60. The first outer portion 22 has the first mounting surface 221A facing one side in the first direction z. The first outer portion 22 has the first opening 23 penetrating the first outer portion 22 from the first mounting surface 221A. With such a configuration, the bonding strength to the wiring board 80 can be improved also in the semiconductor device A30. Furthermore, the semiconductor device A30 has a configuration in common with the semiconductor device A10, thereby achieving the same effect as the semiconductor device A10.

In the semiconductor device A30, the first opening 23 provided in the first outer portion 22 includes the first portion 23A penetrating the first mounting portion 221, and the second portion 23B connected to the first portion 23A and penetrating the first intermediate portion 222. With this configuration, in the mounted assembly B30 shown in FIG. 21, the volume of the first bonding portion 91 contained in the first opening 23 further increases. This increases the anchoring effect exerted by the bonding layer 90 on the first outer portion 22, and the first outer portion 22 is more firmly constrained with respect to the wiring board 80. This further improves the bonding strength of the semiconductor device A30 to the wiring board 80.

Fourth embodiment:

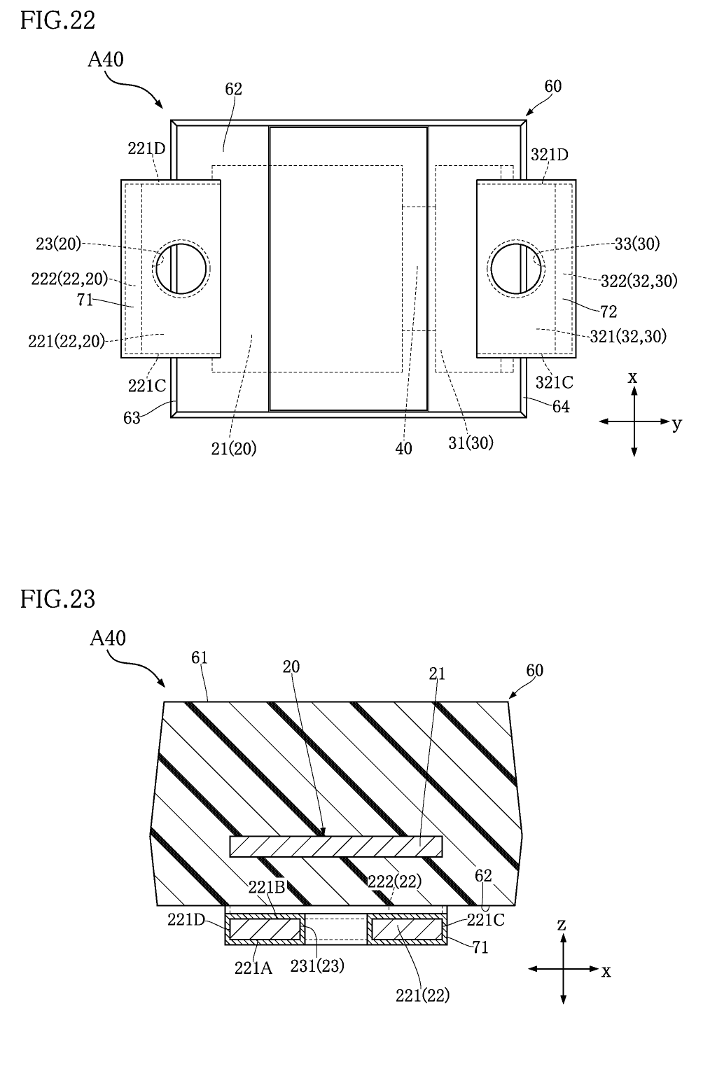

A semiconductor device A40 according to a fourth embodiment of the present disclosure will be described based on FIGS. 22 and 23. In these figures, the elements that are identical or similar to those of the semiconductor device A10 described above are denoted by the same reference signs, and the descriptions thereof are omitted. The cross-sectional position in FIG. 23 corresponds to the cross-sectional position in FIG. 6, which shows the semiconductor device A10.

The semiconductor device A40 differs from the semiconductor device A10 in the configurations of the first outer portion 22 of the first lead 20 and the second outer portion 32 of the second lead 30.

As shown in FIGS. 22 and 23, the first outer portion 22 does not have the second opening 24. As viewed in the first direction z, the first opening 23 is located at the center of the first mounting portion 221 of the first outer portion 22. As shown in FIG. 22, the second outer portion 32 does not have the fourth opening 34. As viewed in the first direction z, the third opening 33 is located at the center of the second mounting portion 321 of the second outer portion 32.

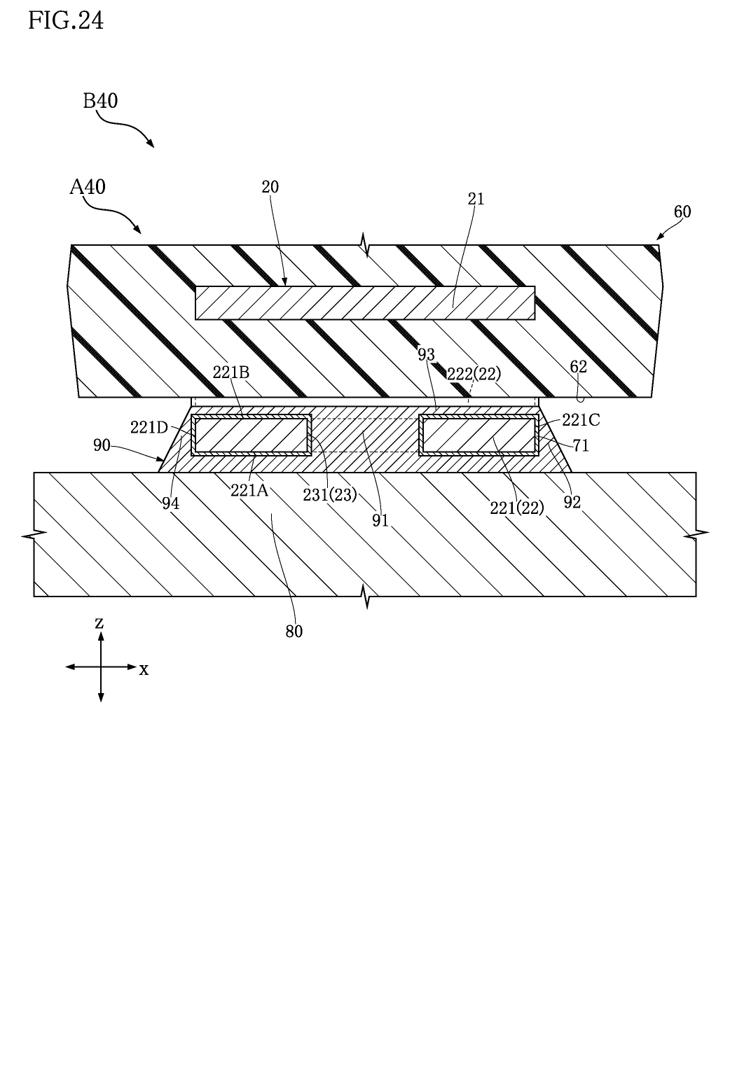

Next, a mounted assembly according to a fourth embodiment of the present disclosure (hereinafter referred to as "mounted assembly B40") will be described based on FIG. 24. The mounted assembly B40 includes the semiconductor device A40, a wiring board 80, and a bonding layer 90.

As shown in FIG. 24, the bonding layer 90 includes a first bonding portion 91, a second bonding portion 92, a third bonding portion 93, and a fourth bonding portion 94. The first bonding portion 91 is received in the first opening 23. The second bonding portion 92 is located opposite the first bonding portion 91 with respect to the first end surface 221C of the first mounting portion 221 of the first outer portion 22 in the second direction x. The third bonding portion 93 is located opposite the first mounting surface 221A of the first mounting portion 221 with respect to the first reverse surface 221B of the first mounting portion 221 of the first outer portion 22 in the first direction z. The fourth bonding portion 94 is located opposite the first bonding portion 91 with respect to the second end surface 221D of the first mounting portion 221. The third bonding portion 93 is connected to the first bonding portion 91 and the second bonding portion 92. The third bonding portion 93 is also connected to the fourth bonding portion 94. Thus, in the mounted assembly B40, the bonding layer 90 surrounds the part of the first mounting portion 221 located between the first opening 23 and the first end surface 221C, as viewed in the third direction y. Also, the bonding layer 90 surrounds the part of the first mounting portion 221 located between the first opening 23 and the second end surface 221D, as viewed in the third direction y.

Next, the effects of the semiconductor device A40 will be described.

The semiconductor device A40 includes the first lead 20, the semiconductor element 10, and the sealing resin 60. The first lead 20 has the first outer portion 22 protruding from the sealing resin 60. The first outer portion 22 has the first mounting surface 221A facing one side in the first direction z. The first outer portion 22 has the first opening 23 penetrating the first outer portion 22 from the first mounting surface 221A. With such a configuration, the bonding strength to the wiring board 80 can be improved also in the semiconductor device A40. Furthermore, the semiconductor device A40 has a configuration in common with the semiconductor device A10, thereby achieving the same effect as the semiconductor device A10.

Fifth embodiment:

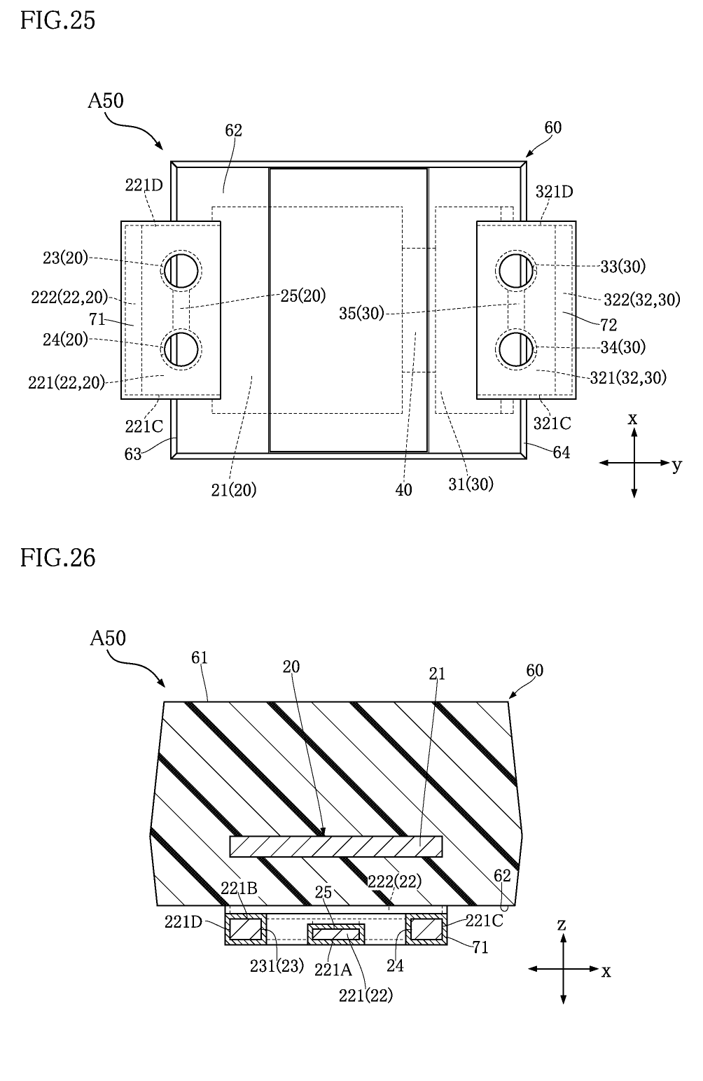

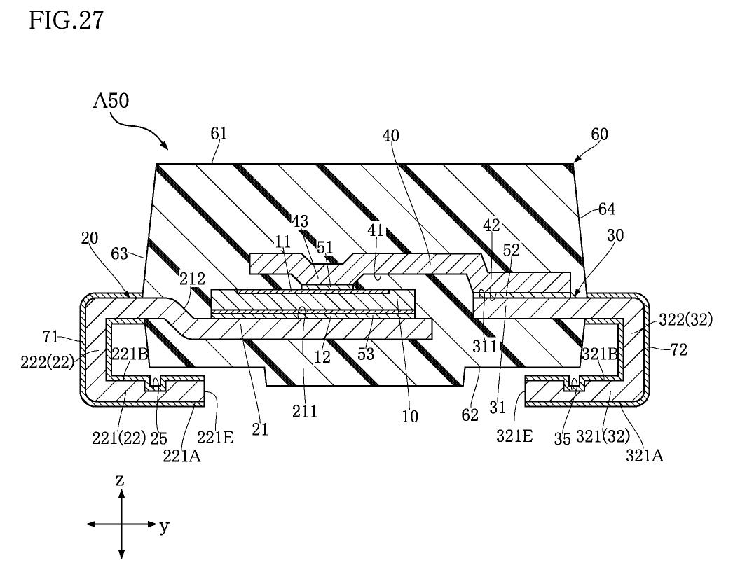

A semiconductor device A50 according to a fifth embodiment of the present disclosure will be described based on FIGS. 25 to 27. In these figures, the elements that are identical or similar to those of the semiconductor device A10 described above are denoted by the same reference signs, and the descriptions thereof are omitted. The cross-sectional position in FIG. 26 corresponds to the cross-sectional position in FIG. 6, which shows the semiconductor device A10. The cross-sectional position in FIG. 27 corresponds to the cross-sectional position in FIG. 8, which shows the semiconductor device A10.

The semiconductor device A50 differs from the semiconductor device A10 in the configurations of the first outer portion 22 of the first lead 20 and the second outer portion 32 of the second lead 30.

As shown in FIGS. 25 to 27, the first mounting portion 221 of the first outer portion 22 has a first recess 25 recessed from the first reverse surface 221B. The first recess 25 extends in the second direction x. The first recess 25 is connected to the first opening 23 and the second opening 24. The dimension of the first recess 25 in the third direction y is smaller than the dimension of each of the first opening 23 and the second opening 24 in the third direction y. A part of the first protective layer 71 is received in the first recess 25.

As shown in FIGS. 25 and 27, the second mounting portion 321 of the second outer portion 32 has a second recess 35 recessed from the second reverse surface 321B. The second recess 35 extends in the second direction x. The second recess 35 is connected to the third opening 33 and the fourth opening 34. The dimension of the second recess 35 in the third direction y is smaller than the dimension of each of the third opening 33 and the fourth opening 34 in the third direction y. A part of the second protective layer 72 is received in the second recess 35.

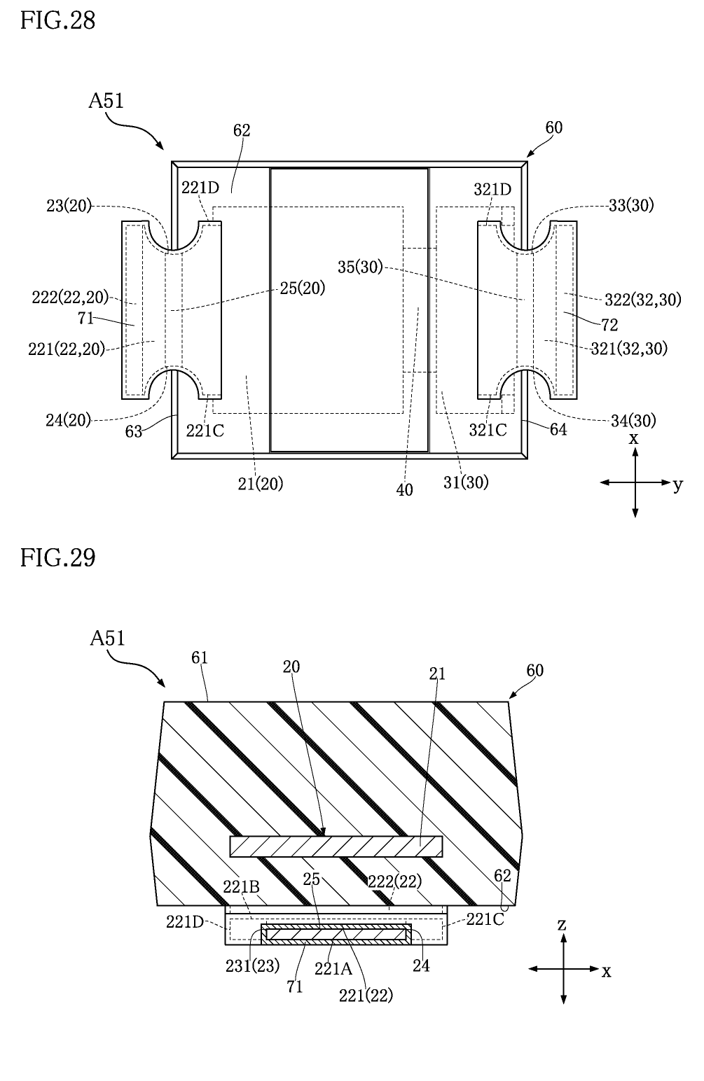

Next, a semiconductor device A51, which is a first variation of the semiconductor device A50, will be described based on FIGS. 28 and 29. The cross-sectional position in FIG. 29 corresponds to the cross-sectional position in FIG. 26.

As shown in FIGS. 28 and 29, the semiconductor device A51 has a configuration in which the first recess 25 and the second recess 35 are provided in the first mounting portion 221 of the first outer portion 22 and the second mounting portion 321 of the second outer portion 32, respectively, in the semiconductor device A20 described above.

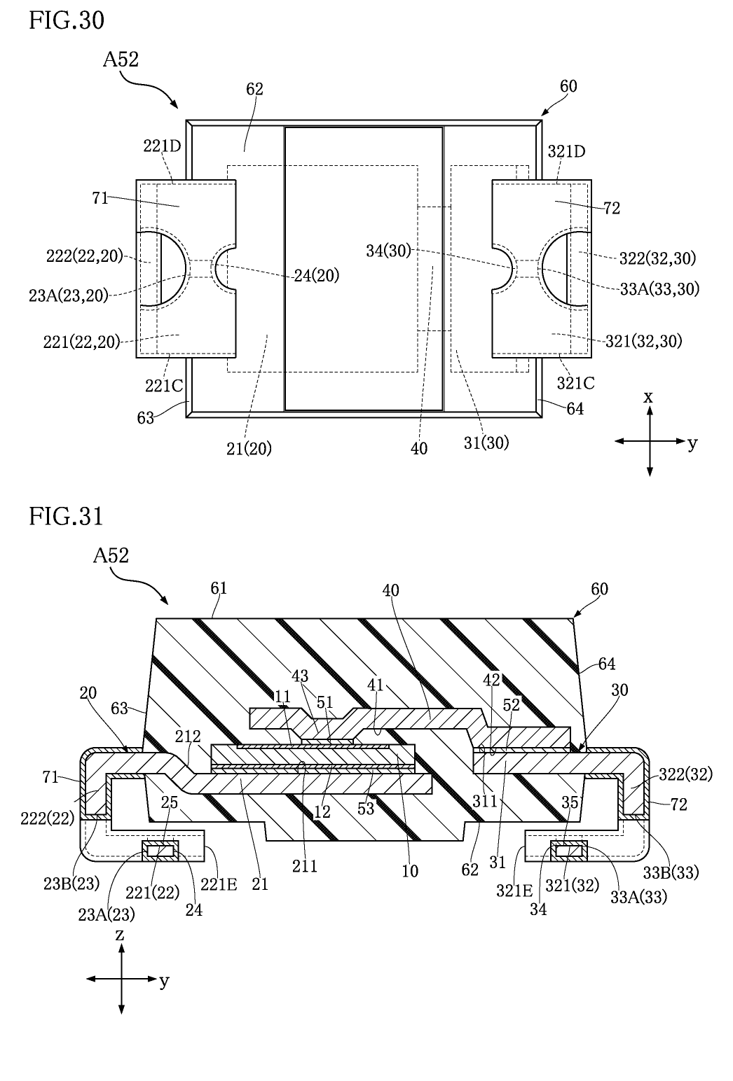

Next, a semiconductor device A52, which is a second variation of the semiconductor device A50, will be described based on FIGS. 30 and 31. The cross-sectional position in FIG. 31 corresponds to the cross-sectional position in FIG. 27.

As shown in FIGS. 30 and 31, the semiconductor device A52 has a configuration in which the first recess 25 and the second recess 35 are provided in the first mounting portion 221 of the first outer portion 22 and the second mounting portion 321 of the second outer portion 32, respectively, in the semiconductor device A30 described above. Each of the first recess 25 and the second recess 35 extends in the third direction y.

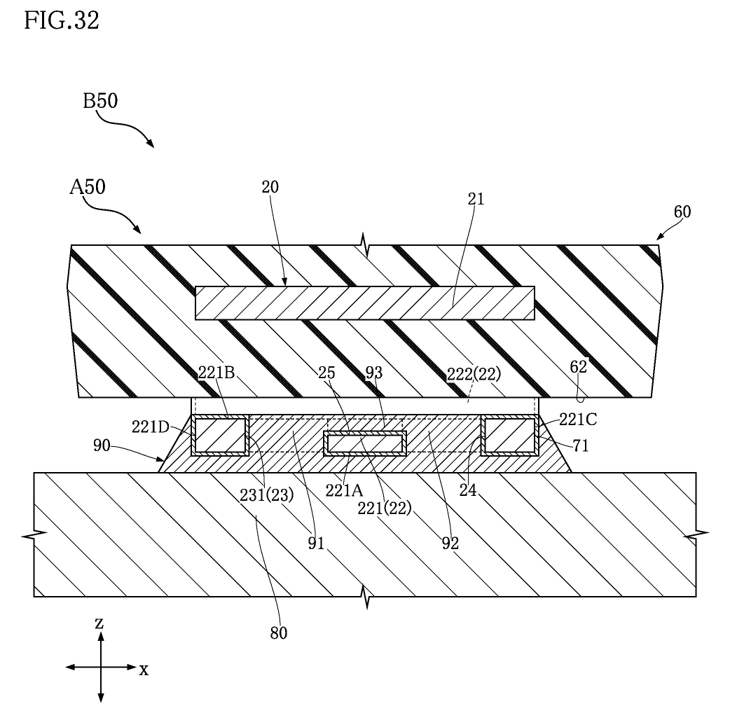

Next, a mounted assembly according to a fifth embodiment of the present disclosure (hereinafter referred to as "mounted assembly B50") will be described based on FIG. 32. The mounted assembly B50 includes the semiconductor device A50, a wiring board 80, and a bonding layer 90.

As shown in FIG. 32, the bonding layer 90 includes a first bonding portion 91, a second bonding portion 92, and a third bonding portion 93. As with the mounted assembly B10, the third bonding portion 93 is connected to the first bonding portion 91 and the second bonding portion 92. Thus, in the mounted assembly B50, the bonding layer 90 surrounds the part of the first mounting portion 221 located between the first opening 23 and the second opening 24, as viewed in the third direction y. Furthermore, in the mounted assembly B50, a part of the third bonding portion 93 is received in the first recess 25.

Next, the effects of the semiconductor device A50 will be described.

The semiconductor device A50 includes the first lead 20, the semiconductor element 10, and the sealing resin 60. The first lead 20 has the first outer portion 22 protruding from the sealing resin 60. The first outer portion 22 has the first mounting surface 221A facing one side in the first direction z. The first outer portion 22 has the first opening 23 penetrating the first outer portion 22 from the first mounting surface 221A. With such a configuration, the bonding strength to the wiring board 80 can be improved also in the semiconductor device A50. The semiconductor device A50 has a configuration in common with the semiconductor device A10, thereby achieving the same effect as the semiconductor device A10.

In the semiconductor device A50, the first mounting portion 221 of the first outer portion 22 has the first recess 25 recessed from the first reverse surface 221B. The first recess 25 is connected to the first opening 23 and the second opening 24. With such a configuration, the first recess 25 promotes the formation of the third bonding portion 93, which is a part of the bonding layer 90, in the mounted assembly B50 shown in FIG. 32. As a result, the first outer portion 22 can be firmly constrained with respect to the wiring board 80.

Sixth embodiment:

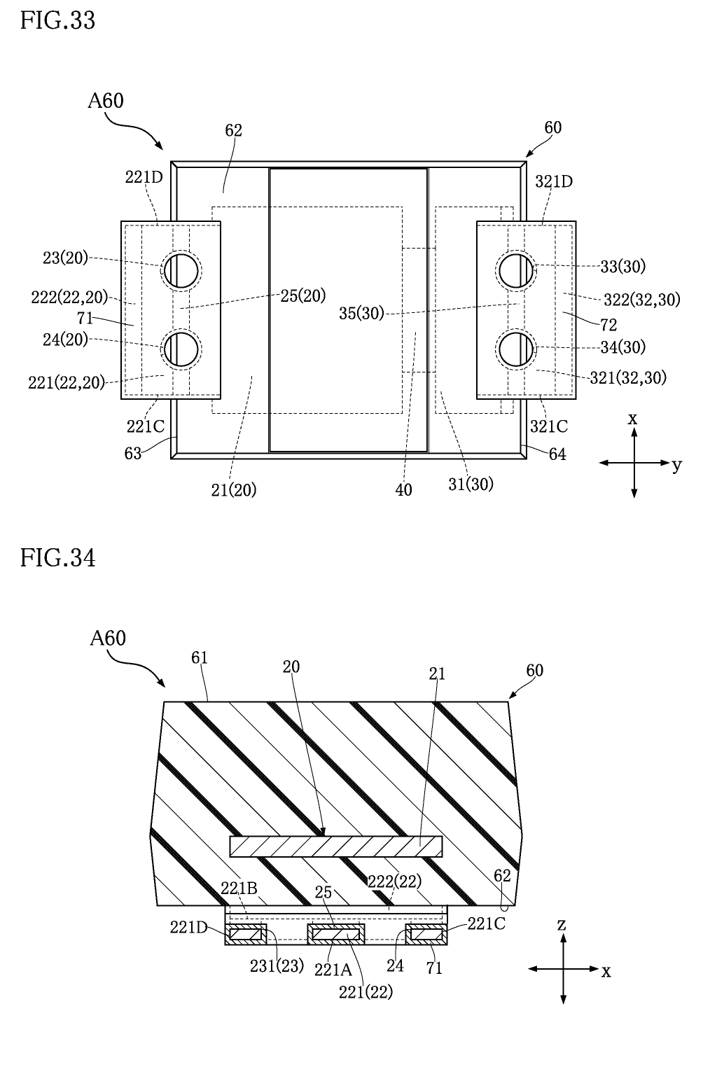

A semiconductor device A60 according to a sixth embodiment of the present disclosure will be described based on FIGS. 33 and 34. In these figures, the elements that are identical or similar to those of the semiconductor device A10 and the semiconductor device A50 described above are denoted by the same reference signs, and the descriptions thereof are omitted. The cross-sectional position in FIG. 34 corresponds to the cross-sectional position in FIG. 6, which shows the semiconductor device A10.

The semiconductor device A60 differs from the semiconductor device A50 in the configurations of the first outer portion 22 of the first lead 20 and the second outer portion 32 of the second lead 30.

As shown in FIGS. 33 and 34, the first recess 25 provided in the first mounting portion 221 of the first outer portion 22 is connected to the first end surface 221C and the second end surface 221D of the first mounting portion 221. As shown in FIG. 33, the second recess 35 provided in the second mounting portion 321 of the second outer portion 32 is connected to the fourth end surface 321C and the fifth end surface 321D of the second mounting portion 321.

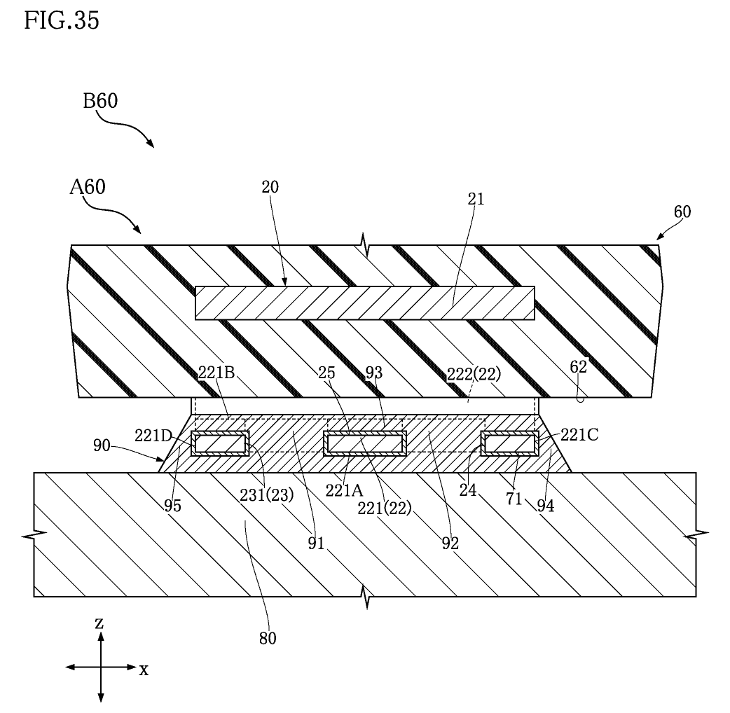

Next, a mounted assembly according to a sixth embodiment of the present disclosure (hereinafter referred to as "mounted assembly B60") will be described based on FIG. 35. The mounted assembly B60 includes the semiconductor device A60, a wiring board 80, and a bonding layer 90.

As shown in FIG. 35, the bonding layer 90 includes a first bonding portion 91, a second bonding portion 92, a third bonding portion 93, a fourth bonding portion 94, and a fifth bonding portion 95. The first bonding portion 91 is received in the first opening 23. The second bonding portion 92 is received in the second opening 24. The fourth bonding portion 94 is located opposite the second bonding portion 92 with respect to the first end surface 221C of the first mounting portion 221 of the first outer portion 22 in the second direction x. The fifth bonding portion 95 is located opposite the first bonding portion 91 with respect to the second end surface 221D of the first mounting portion 221 in the second direction x. The third bonding portion 93 is connected to the first bonding portion 91 and the second bonding portion 92. The third bonding portion 93 is also connected to the fourth bonding portion 94 and the fifth bonding portion 95. Thus, in the mounted assembly B60, the bonding layer 90 surrounds the part of the first mounting portion 221 located between the first opening 23 and the second opening 24, as viewed in the third direction y. Also, the bonding layer 90 surrounds the part of the first mounting portion 221 located between the first opening 23 and the second end surface 221D and the part of the first mounting portion 221 located between the second opening 24 and the first end surface 221C, as viewed in the third direction y. Furthermore, in the mounted assembly B60, a part of the third bonding portion 93 is received in the first recess 25.

Next, the effects of the semiconductor device A60 will be described.

The semiconductor device A60 includes the first lead 20, the semiconductor element 10, and the sealing resin 60. The first lead 20 has the first outer portion 22 protruding from the sealing resin 60. The first outer portion 22 has the first mounting surface 221A facing one side in the first direction z. The first outer portion 22 has the first opening 23 penetrating the first outer portion 22 from the first mounting surface 221A. With such a configuration, the bonding strength to the wiring board 80 can be improved also in the semiconductor device A60. Furthermore, the semiconductor device A60 has a configuration in common with the semiconductor device A10, thereby achieving the same effect as the semiconductor device A10.

In the semiconductor device A60, the first recess 25 provided in the first mounting portion 221 of the first outer portion 22 is connected to the first end surface 221C and the second end surface 221D of the first mounting portion 221. With such a configuration, in the mounted assembly B60 shown in FIG. 35, the volume of the bonding layer 90 surrounding a part of the first outer portion 22 further increases as compared with that in the mounted assembly B50. As a result, the first outer portion 22 can be further firmly constrained with respect to the wiring board 80.

Seventh embodiment:

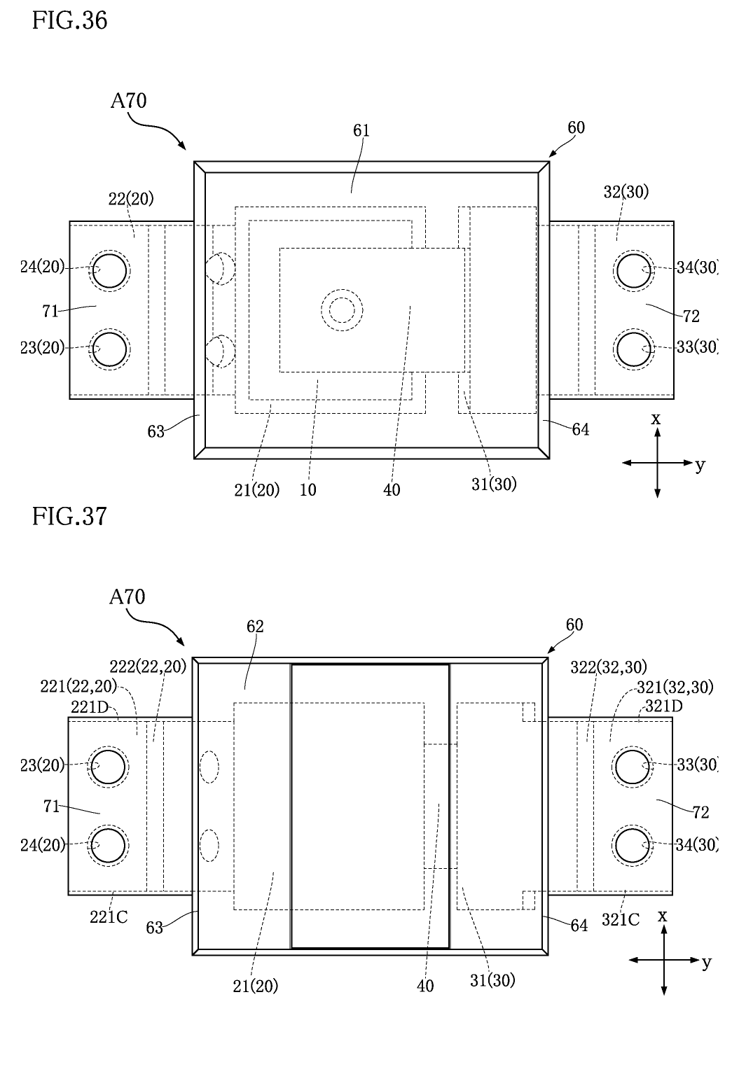

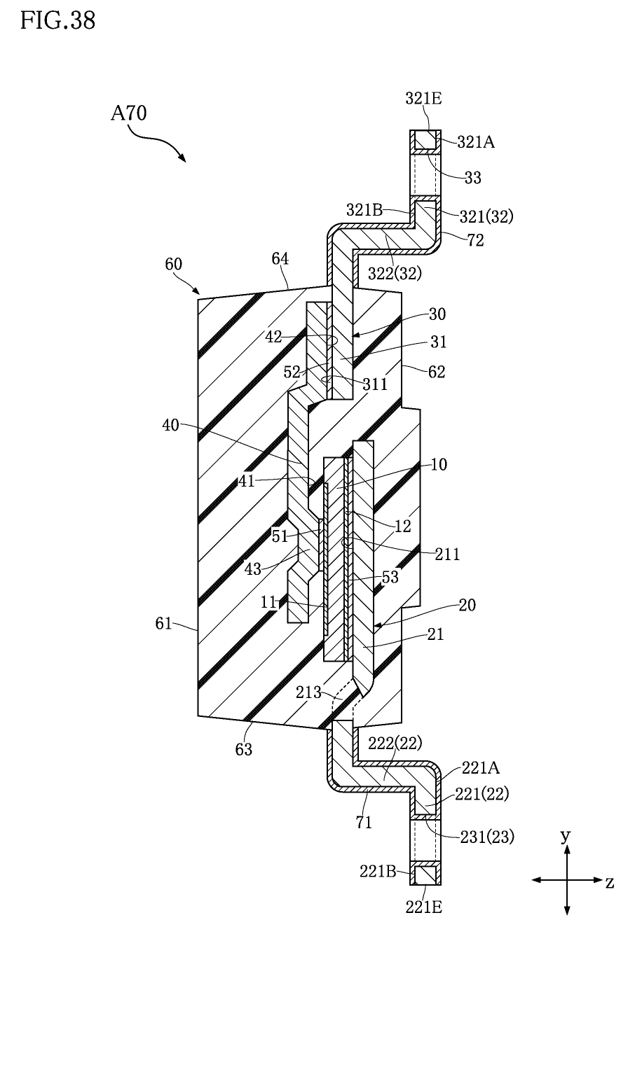

A semiconductor device A70 according to a seventh embodiment of the present disclosure will be described based on FIGS. 36 to 38. In these figures, the elements that are identical or similar to those of the semiconductor device A10 described above are denoted by the same reference signs, and the descriptions thereof are omitted. The cross-sectional position in FIG. 38 corresponds to the cross-sectional position in FIG. 8, which shows the semiconductor device A10.

The semiconductor device A70 differs from the semiconductor device A50 in the configurations of the first outer portion 22 of the first lead 20 and the second outer portion 32 of the second lead 30.

As shown in FIGS. 36 to 38, the first mounting portion 221 of the first outer portion 22 is located opposite the first inner portion 21 with respect to the first intermediate portion 222 of the first outer portion 22 in the third direction y. As viewed in the first direction z, the first mounting portion 221 is spaced apart from the sealing resin 60. Thus, as viewed in the first direction z, the first opening 23 and the second opening 24 provided in the first outer portion 22 are spaced apart from the sealing resin 60.

As shown in FIGS. 36 to 38, the second mounting portion 321 of the second outer portion 32 is located opposite the second inner portion 31 with respect to the second intermediate portion 322 of the second outer portion 32 in the third direction y. As viewed in the first direction z, the second mounting portion 321 is spaced apart from the sealing resin 60. Thus, as viewed in the first direction z, the third opening 33 and the fourth opening 34 provided in the second outer portion 32 are spaced apart from the sealing resin 60.

Next, the effects of the semiconductor device A70 will be described.

The semiconductor device A70 includes the first lead 20, the semiconductor element 10, and the sealing resin 60. The first lead 20 has the first outer portion 22 protruding from the sealing resin 60. The first outer portion 22 has the first mounting surface 221A facing one side in the first direction z. The first outer portion 22 has the first opening 23 penetrating the first outer portion 22 from the first mounting surface 221A. With such a configuration, the bonding strength to the wiring board 80 can be improved also in the semiconductor device A70. Furthermore, the semiconductor device A70 has a configuration in common with the semiconductor device A10, thereby achieving the same effect as the semiconductor device A10.

The present disclosure is not limited to the above-described embodiments. Various modifications in design may be made freely in the specific structure of each part of the present disclosure.

1. A semiconductor device comprising:
a first lead;
a semiconductor element electrically connected to the first lead; and
a sealing resin covering a part of the first lead and covering the semiconductor element, wherein
the first lead includes a first outer portion protruding from the sealing resin,
the first outer portion includes a first mounting surface facing one side in a first direction, and
the first outer portion includes a first opening penetrating the first outer portion from the first mounting surface.

2. The semiconductor device according to claim 1, further comprising a first protective layer that covers at least a part of the first outer portion and is conductive, wherein
the first outer portion includes a first end surface facing one side in a second direction orthogonal to the first direction and spaced apart from the first opening, and
the first protective layer covers the first end surface.

3. The semiconductor device according to claim 2, wherein the first outer portion includes a first reverse surface facing away from the first mounting surface in the first direction, and
the first protective layer covers the first reverse surface.

4. The semiconductor device according to claim 3, wherein the first outer portion includes an inner peripheral surface defining the first opening and connected to the first mounting surface and the first reverse surface, and
the first protective layer covers the inner peripheral surface.

5. The semiconductor device according to claim 3, wherein the first outer portion includes a second opening penetrating the first outer portion from the first mounting surface, and
the second opening is spaced apart from the first opening in a direction orthogonal to the first direction.

6. The semiconductor device according to claim 5, wherein the first outer portion includes a first mounting portion including the first mounting surface, the first end surface and the first reverse surface, and a first intermediate portion rising from the first mounting portion in the first direction, and
the first protective layer covers at least a part of the first intermediate portion.

7. The semiconductor device according to claim 6, wherein the first mounting portion includes a second end surface facing away from the first end surface in the second direction and spaced apart from the second opening, and
the first protective layer covers the second end surface.

8. The semiconductor device according to claim 7, wherein the second opening is located between the first end surface and the first opening in the second direction.

9. The semiconductor device according to claim 8, wherein the first opening and the second opening are located inward of a peripheral edge of the first mounting portion as viewed in the first direction.

10. The semiconductor device according to claim 9, wherein a size of a cross section of the first opening in a direction orthogonal to the first direction increases from the first mounting surface to the first reverse surface.

11. The semiconductor device according to claim 8, wherein the first opening is connected to the second end surface.

12. The semiconductor device according to claim 11, wherein the second opening is connected to the first end surface.

13. The semiconductor device according to claim 7, wherein the first opening includes a first portion penetrating the first mounting portion and a second portion connected to the first portion and penetrating the first intermediate portion.

14. The semiconductor device according to claim 6, wherein the first mounting portion includes a first recess recessed from the first reverse surface, and
the first recess is connected to the first opening and the second opening.

15. The semiconductor device according to claim 6, wherein the first reverse surface faces the sealing resin.

16. The semiconductor device according to claim 15, wherein the first opening overlaps with the sealing resin as viewed in the first direction.

17. The semiconductor device according to claim 16, wherein a gap is provided between the first reverse surface and the sealing resin in the first direction.

18. The semiconductor device according to claim 17, wherein the first lead includes a first inner portion connected to the first outer portion and covered with the sealing resin, and
the semiconductor element is conductively bonded to one side of the first inner portion in the first direction.

19. A mounted assembly comprising:
the semiconductor device according to claim 3;
a wiring board facing the first mounting surface; and
a bonding layer conductively bonding the wiring board and the first outer portion, wherein
the bonding layer includes a first bonding portion received in the first opening, a second bonding portion located opposite the first bonding portion with respect to the first end surface in the second direction, and a third bonding portion located opposite the first mounting surface with respect to the first reverse surface in the first direction, and
the third bonding portion is connected to the first bonding portion and the second bonding portion.

20. A mounted assembly comprising:
the semiconductor device according to claim 5;
a wiring board facing the first mounting surface; and
a bonding layer conductively bonding the wiring board and the first outer portion, wherein
the bonding layer includes a first bonding portion received in the first opening, a second bonding portion received in the second opening, and a third bonding portion located opposite the first mounting surface with respect to the first reverse surface in the first direction, and
the third bonding portion is connected to the first bonding portion and the second bonding portion.
